(19) United States
(12) Patent Application Publication
(10) Pub. No.: US 2025/0324901 A1
(43) Pub. Date: Oct. 16, 2025

(54) METHOD FOR DRYING DISPLAY PANEL AND APPARATUS FOR DRYING THE SAME

(71) Applicant: Samsung Display Co., LTD., Yongin-si (KR)

(72) Inventor: JONGJANG PARK, Yongin-si (KR)

(73) Assignee: Samsung Display Co., LTD., Yongin-si (KR)

(21) Appl. No.: 19/068,396

(22) Filed: Mar. 3, 2025

(30) Foreign Application Priority Data
Apr. 11, 2024 (KR) 10-2024-0048749

(51) Int. Cl. H10K 71/40; H10K 59/12

(52) U.S. Cl. CPC H10K 71/40; H10K 59/1201

(57) ABSTRACT

A method for drying a display panel includes providing a display panel including a first light-emitting element, a second light-emitting element, and a third light-emitting element on a stage including a thermal heater; providing an infrared heater on the stage; providing an infrared blocking mask between the display panel and the infrared heater; and baking at least one of the first light-emitting element and the second light-emitting element, and the third light-emitting element, at different bake temperatures by the thermal heater and the infrared heater.

### CROSS-REFERENCE TO RELATED APPLICATION

This application claims priority to and benefits of Korean Patent Application No. 10-2024-0048749, under 35 U.S.C. § 119, filed on Apr. 11, 2024, in the Korean Intellectual Property Office, the entire contents of which are incorporated herein by reference.

### BACKGROUND

### 1. Technical Field

Embodiments relate to a method for drying a display panel and an apparatus for drying the display panel, and more specifically, to a drying method and a drying apparatus for forming pixels of a light emitting display panel.

### 2. Description of the Related Art

Liquid crystal displays, emissive display devices, etc. are used as display devices that display images. The liquid crystal display is a display device that includes a backlight unit and displays an image by blocking or transmitting light emitted from the backlight unit. For example, an emissive display device is a display device that has recently been attracting attention, and since it has its own light emitting characteristic, unlike the LCD, it does not require a separate light source.

The display device may include a display panel that provides a screen for displaying images. For example, the emissive display device may include a light emitting display panel, and a plurality of pixels may be arranged on the light emitting display panel. Each pixel may be implemented as a light-emitting element. In manufacturing the light emitting display panel, various processes may be performed, such as a process of depositing various materials on a substrate or a heat treatment process as well as a drying process and a baking process. The thermal treatment process may be performed to induce physical or chemical changes in the material, to form a layer or film with desired characteristics, or to remove a carrier liquid.

### SUMMARY

A typical heat treatment process entirely applies the same temperature to an object being heated, and it may be difficult to provide differential temperatures for each pixel, which is a fine region in the display panel. Accordingly, in case that the temperature to be applied is different depending on each color of the pixels, a manufacturing time and a cost may increase because the heat treatment process may be divided into a plurality of steps.

Embodiments are intended to provide a method for drying a display panel and an apparatus for drying the display panel that provide different bake temperatures for the pixels of different colors.

However, embodiments are not limited to those set forth herein. The above and other embodiments will become more apparent to one of ordinary skill in the art to which the disclosure pertains by referencing the detailed description of the disclosure given below.

A method for drying a display panel according to an embodiment includes providing: a display panel including a first light-emitting element, a second light-emitting element, and a third light-emitting element on a stage including a thermal heater; providing an infrared heater on the stage; providing an infrared blocking mask between the display panel and the infrared heater; and baking at least one of the first light-emitting element, the second light-emitting element, and the third light-emitting element at different bake temperatures by the thermal heater and the infrared heater.

The infrared blocking mask may include an infrared transmitting hole at a position corresponding to the first light-emitting element and the second light-emitting element, and may include an infrared blocking layer at a position corresponding to the third light-emitting element.

The thermal heater may apply heat to the first light-emitting element, the second light-emitting element, and the third light-emitting element, and the infrared heater may apply heat to the first light-emitting element and the second light-emitting element by the infrared transmitting hole.

The infrared blocking layer may include at least one of an infrared reflection layer or an infrared absorption layer.

The bake temperature for the third light-emitting element may be lower than the bake temperature for the first light-emitting element and the second light-emitting element.

The first light-emitting element, the second light-emitting element, and the third light-emitting element may each include one of an organic emission layer, a quantum dot light emitting layer, or an organic light emitting-quantum dot light emitting layer.

The first light-emitting element and the second light-emitting element may include the quantum dot light emitting layer, and the third light-emitting element may include the organic emission layer.

Setting the temperature of heat provided by the thermal heater to be lower than the temperature of heat provided by the infrared heater may be further included.

Providing the infrared blocking mask may include being mounted directly below the infrared heater or directly above the display panel.

The first light-emitting element, the second light-emitting element, and the third light-emitting element may emit different colors of light.

A method for drying a display panel according to another embodiment includes: providing a display panel including a first light-emitting element, a second light-emitting element, and a third light-emitting element on a stage including a thermal heater; providing an infrared blocking mask on the stage; providing an infrared heater on the infrared blocking mask; and baking at least one of the first light-emitting element, the second light-emitting element, and the third light-emitting element at different temperatures by the thermal heater and the infrared heater, wherein the thermal heater applies heat to the first light-emitting element, the second light-emitting element, and the third light-emitting element, the infrared heater applies heat to at least one of the first light-emitting element, the second light-emitting element, and the third light-emitting element due to the infrared blocking mask.

The infrared blocking mask may include an infrared blocking layer at a position corresponding to one or more of the first light-emitting element, the second light-emitting element, and the third light-emitting element.

The infrared blocking layer may include at least one of an infrared reflection layer or an infrared absorption layer.

Setting the temperature of heat provided by the thermal heater to be lower than the temperature of heat provided by the infrared heater may be further included.

Mounting the infrared blocking mask directly below the infrared heater or directly above the display panel may be further included.

The infrared blocking mask may be formed using at least one method of a photolithography or an inkjet process.

A drying apparatus of a display panel according to an embodiment includes a drying chamber, a stage disposed inside the drying chamber and including a thermal heater, an infrared blocking mask disposed on the stage, and an infrared heater disposed on the infrared blocking mask.

The infrared blocking mask may include an infrared blocking layer and an infrared transmitting hole.

The infrared blocking layer may include at least one of an infrared reflection layer or an infrared absorption layer.

The infrared blocking mask may be disposed directly below the infrared heater.

According to embodiments, the method of drying the pixels of different colors at the different bake temperatures may be provided by the thermal heater, the infrared heater, and the infrared reflection-absorption mask. Accordingly, the manufacturing time of the display panel may be shortened and the cost may be reduced.

### BRIEF DESCRIPTION OF THE DRAWINGS

FIG. 1 is a schematic view of a drying apparatus according to an embodiment.

FIG. 2 is a flowchart for a drying method according to an embodiment.

FIG. 3 is a process view that schematically shows a mask manufacturing process according to an embodiment.

FIG. 4 is a process drawing schematically showing a mask manufacturing process according to another embodiment.

FIG. 5 is a schematic cross-sectional view of a display panel according to an embodiment.

FIG. 6 is a schematic cross-sectional view of a display panel according to another embodiment.

FIG. 7 is a schematic cross-sectional view of a display panel according to another embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

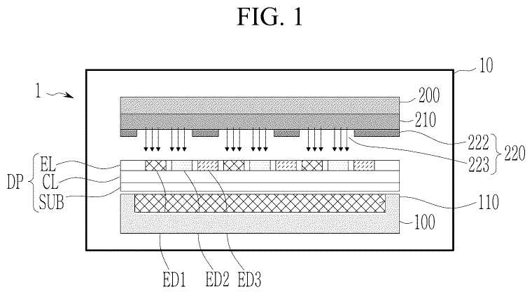

FIG. 1 is a schematic view of a drying apparatus according to an embodiment.

Referring to FIG. 1, a drying apparatus 1 according to an embodiment may be used to dry layers constituting pixels of a display panel, for example a light emitting layer. For example, layers of the pixels may be formed using an inkjet process, and a drying apparatus 1 may bake the layers of light-emitting elements to a selected temperature. Additionally, the scope of the disclosure extends to all processes that manufacture thin films using an ink, for example, all processes that manufacture a printing OLED, a solar cell, a sensor, and a quantum dot (QD) filter.

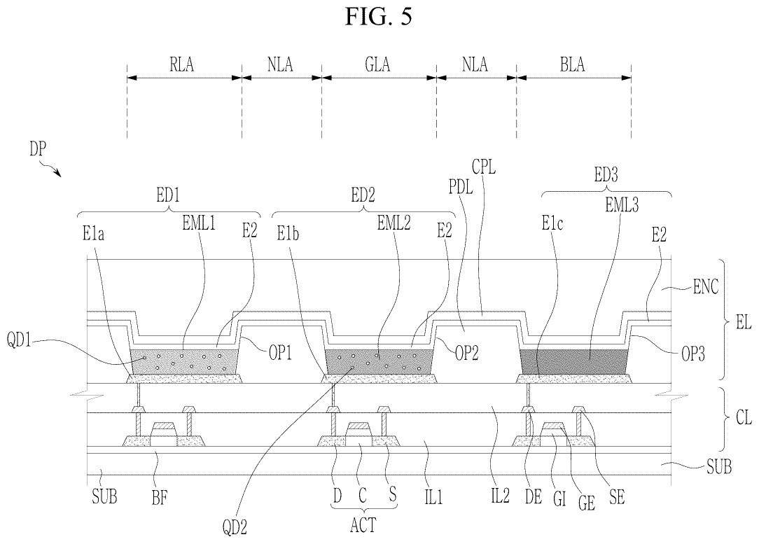

For better understanding and case of description, in FIG. 1, the display panel DP applicable to the drying apparatus 1 is shown as a substrate SUB, a circuit element layer CL, and a light-emitting element layer EL. The structure of the display panel DP will be described later with reference to FIG. 5 to FIG. 7 according to an embodiment.

The circuit element layer CL and the light-emitting element layer EL may be disposed on the substrate SUB. The circuit element layer CL may include a semiconductor layer ACT for driving the light emitting layer. The light-emitting element layer EL may be disposed on the circuit element layer CL. The light-emitting element layer EL may include first, second, and third light-emitting elements ED1, ED2, and ED3 that emit different colors. For example, the first light-emitting element ED1 may emit red light, the second light-emitting element ED2 may emit green light, and the third light-emitting element ED3 may emit blue light. The first, second, and third light-emitting elements ED1, ED2, and ED3 may correspond to a red light emission area RLA, a green light emission area GLA, and a blue light emission area BLA or red, green, and blue pixels, respectively. The first, second, and third light-emitting elements ED1, ED2, and ED3 may include a quantum dot light emitting layer including quantum dots, or may include an organic emission layer including organic materials. Each of the light-emitting elements ED1, ED2, and ED3 may be an organic light emitting element or a quantum dot light-emitting element. A specific configuration of each element layer is described later in FIG. 5 to FIG. 7.

The drying apparatus 1 may bake each light-emitting element or the light-emitting elements of a specific color at a different temperature from the light-emitting elements of other colors. The drying apparatus 1 may include a drying chamber 10, and a stage 100, a holder 200, an infrared heater 210, and an infrared blocking mask 220 disposed in the drying chamber 10.

The drying chamber 10 may load the display panel DP that has undergone the inkjet process in order to perform the bake process for the display panel DP. The stage 100, a thermal heater 110, the holder 200, the infrared heater 210, and the infrared blocking mask 220 may be disposed inside the drying chamber 10.

The stage 100 may support the display panel DP during the bake process. The stage 100 may be a tray or a chuck for the display panel. The stage 100 may be implemented to move up and down to adjust the distance from the infrared heater 210.

In case that the substrate SUB includes a plastic material, a carrier substrate made of glass, etc. may be disposed between the thermal heater 110 and the substrate SUB. The carrier substrate may prevent the plastic material of the substrate SUB from being directly heated and changing characteristics of the substrate SUB.

The stage 100 may include a thermal heater 110. The thermal heater 110 may be arranged to be in contact with the upper surface of the stage 100 or close to the upper surface of the stage 100, and may heat the display panel DP mounted on the stage 100. The thermal heater 110 may heat the entire display panel DP disposed on the stage 100. The thermal heater 110 may be set to have an appropriate temperature in order to remove a solvent of an ink on the display panel DP. For example, the selected temperature of the thermal heater 110 may be adjusted to an organic emission layer, which has a relatively lower bake temperature than the quantum dot light emitting layer.

The holder 200 may be fixed or movably disposed at a selected position inside the drying chamber 10. In case that the display panel DP is mounted on the stage 100, the holder 200 may be disposed on an upper part of the display panel DP. The holder 200 may hold the infrared heater 210 and be moved up and down to adjust the distance from the stage 100 or the display panel DP mounted on the stage 100. The holder 200 may be implemented to move left and right to align with the stage 100 or the display panel DP mounted on the stage 100.

The holder 200 may fix the infrared heater 210 at a selected position. The holder 200 may be fixed in the drying chamber 10 or movably disposed in the drying chamber 10. The infrared heater 210 may be disposed in contact with the lower surface of the holder 200 or may be arranged close to the lower surface of the holder 200. The infrared heater 210 may apply heat with infrared rays with linearity to the display panel DP at a plurality of positions between the display panel DP and the holder 200.

The infrared heater 210 may be set to have an appropriate temperature to remove the solvent of ink on the display panel DP. For example, the selected temperature of the infrared heater 210 may be set as a higher temperature than that of the thermal heater 110, in a line with a quantum dot light emitting layer, which has a relatively higher bake temperature than the organic emission layer. Infrared rays emitted by the infrared heater 210 may be partially blocked by the infrared blocking mask 220 disposed below the infrared heater 210.

The infrared blocking mask 220 may be disposed below the infrared heater 210. The infrared blocking mask 220 may be disposed in contact with the bottom (or lower surface) of the infrared heater 210 or close to the lower surface of the infrared heater 210, and may partially block infrared rays emitted from the infrared heater 210 at the plurality of positions between the display panel DP and the infrared heater 210. For example, the infrared blocking mask 220 may be mounted on a stand disposed between the display panel DP and the infrared heater 210, but the range of the disclosure is not limited thereto. For example, the infrared blocking mask 220 may be implemented to move up and down to adjust the distance from the display panel DP and the infrared heater 210.

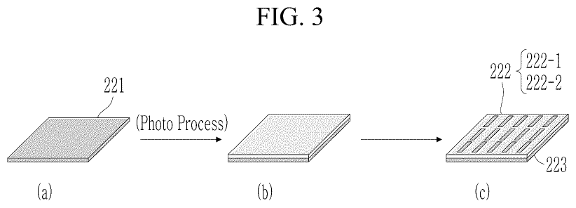

The infrared blocking mask 220 may include a glass substrate 221, an infrared blocking layer 222, and an infrared transmitting hole 223. The infrared blocking mask 220 may have a structure in which the infrared blocking layer 222 and the infrared transmitting hole 223 are formed on the glass substrate 221. The infrared blocking layer 222 may be either a reflection layer that reflects infrared rays (222-1, referring to FIG. 3) or an absorption layer that absorbs infrared rays (222-2, referring to FIG. 3).

The infrared blocking layer 222 may be formed at a position corresponding to the third light-emitting element ED3. The infrared blocking layer 222 may overlap the third light-emitting element ED3. The infrared blocking layer 222 may block infrared rays emitted from the infrared heater 210 from reaching the third light-emitting element ED3, thereby preventing the bake temperature of the light emitting layer in the third light-emitting element ED3 from increasing. However, embodiments are not limited thereto, and the infrared blocking layer 222 may be formed at positions corresponding to the first or second light-emitting elements ED1 and ED2 in addition to the third light-emitting element ED3, thereby blocking infrared rays.

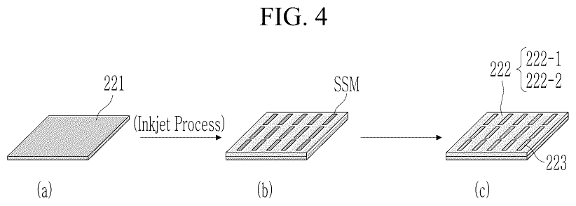

The infrared transmitting hole 223 may be a region in which the infrared blocking layer 222 is not formed. The infrared transmitting hole 223 may be formed at positions corresponding to the first and second light-emitting elements ED1 and ED2. The infrared transmitting hole 223 may overlap the first and second light-emitting elements ED1 and ED2. The infrared transmitting hole 223 may transmit the infrared rays emitted from the infrared heater 210 and may allow the infrared rays to reach the first and second light-emitting elements ED1 and ED2, so that the bake temperature of the light emitting layer in the first and second light-emitting elements ED1 and ED2 may be increased. However, embodiments are not limited thereto, and the infrared transmitting hole 223 may be formed at a position corresponding to the third light-emitting element ED3 in addition to the first and second light-emitting elements ED1 and ED2, so that the infrared rays may reach the third light-emitting element ED3. The information on the method of forming the infrared blocking layer 222 and the infrared transmitting hole 223 of the infrared blocking mask 220 will be described later with reference to FIG. 3 and FIG. 4.

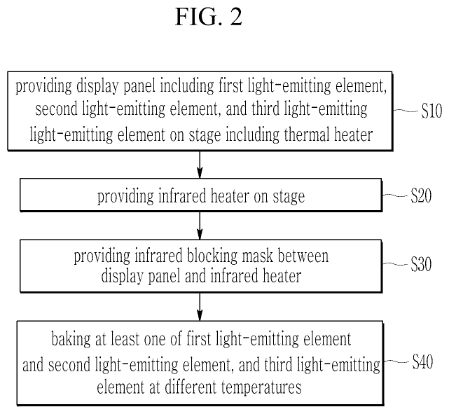

FIG. 2 is a schematic flowchart of a drying method according to an embodiment.

As shown in FIG. 2, the drying method according to an embodiment may include a step S10 of providing a display panel DP including first, second, and third light-emitting elements ED1, ED2, and ED3 on a stage 100 including a thermal heater 110, a step S20 of providing an infrared heater 210 on the stage 100, and a step S30 of providing an infrared blocking mask 220 between the bottom (or lower surface) of the infrared heater 210 and the display panel DP.

For example, the stage 100, the holder 200, the infrared heater 210, and the infrared blocking mask 220 may each be moved up and down to adjust the distance from each other. The infrared blocking mask 220 may be disposed below (e.g., directly below) the infrared heater 210 or above (e.g., directly above) the display panel DP as well as the substrate SUB. For example, the more detailed information about the stage 100, the holder 200, and the infrared blocking mask 220 refers to the above description.

The drying method may include a process S40 of baking at least one of the light emitting layers of the first and second light-emitting elements ED1 and ED2 and the light emitting layer of the third light-emitting element ED3 at different temperatures through the thermal heater 110 and the infrared heater 210. For example, the bake temperature applied to the light emitting layer of the third light-emitting element ED3 may be lower than the bake temperature applied to the light emitting layer of the first and second light-emitting elements ED1 and ED2. However, embodiments are not limited thereto, and the drying method may include baking any one or more of the light emitting layers of the first, second, and third light-emitting elements ED1, ED2, and ED3 at different temperatures.

For example, the thermal heater 110 may provide heat to all light emitting layers of the first, second, and third light-emitting elements ED1, ED2, and ED3. Due to the infrared blocking mask 220, the infrared heater 210 may not provide additional heat to the light emitting layer of the third light-emitting element ED3, but may provide additional heat to the light emitting layers of the first and second light-emitting elements ED1 and ED2. The infrared blocking mask 220 may include an infrared blocking layer 222 at the position corresponding to the third light-emitting element ED3. The infrared blocking layer 222 may further include either an infrared reflection layer 222-1 or an infrared absorption layer 222-2. However, embodiments are not limited thereto, and the infrared heater 210 may apply heat to any one or more of the first, second, and third light-emitting elements ED1, ED2, and ED3, and the position of the infrared blocking layer 222 may be formed to correspond to a light-emitting element to which the infrared heater 210 may not apply heat. For example, more detailed information about the infrared blocking mask 220 may refer to the above descriptions.

For example, the first, second, and third light-emitting elements ED1, ED2, and ED3 may further include an inkjet process for an organic light emitting element, an inkjet process for a quantum dot light-emitting element, or an inkjet process for an organic light emitting-quantum dot light-emitting element convergence type. For example, the third light-emitting element ED3 may be a device with the lower bake temperature than the first and second light-emitting elements ED1 and ED2. The first and second light-emitting elements ED1 and ED2 may be a quantum dot, and the third light-emitting element ED3 may be a light-emitting element including an organic material. More detailed information on the configurations of the first, second, and third light-emitting elements ED1, ED2, and ED3 will refer to the embodiment of the display panel DP described later.

For example, the temperature provided by the thermal heater 110 may be lower than the temperature provided by the infrared heater 210.

The infrared blocking mask 220 may be manufactured using at least one method of a photolithography or inkjet process. More detailed information about the manufacturing process of the infrared blocking mask 220 may refer to embodiments of FIG. 3 and FIG. 4 described later.

FIG. 3 is a process view that schematically shows a mask manufacturing process according to an embodiment.

Referring to FIG. 3, the process of manufacturing the infrared blocking mask 220 through the photolithography process is shown. For example, the infrared blocking mask 220 may include an infrared blocking layer 222 and an infrared transmitting hole 223. The infrared blocking layer 222 may be at least one of a reflection layer 222-1 that reflects infrared rays and an absorption layer 222-2 that absorbs infrared rays. The reflection layer 222-1 may be formed of metal materials such as silver (Ag) and aluminum (Al), and the absorption layer 222-2 may be formed of a material capable of absorbing infrared rays such as antimony oxide, tin oxide, tungsten oxide, titanium oxide, an infrared absorption polymer, an organic-inorganic solar cell material, and a metamaterial.

The manufacturing process may proceed in order of a step (a), a step (b), and a step (c) in FIG. 3. Referring to the step (a), a glass substrate 221 from which foreign substances have been removed is prepared, and then a material that reflects or absorbs infrared rays is applied on (e.g., entirely on) the glass substrate 221. More detailed information about the material may refer to the above descriptions. In the step (b), the material disposed in the area where infrared rays may pass through may be removed through the photolithography process. In the step (c), the area where the applied material remains may form the infrared blocking layer 222, and the area where the applied material is removed may form the infrared transmitting hole 223.

FIG. 4 is a process view that schematically shows a mask manufacturing process according to an embodiment.

Referring to FIG. 4, the process of manufacturing the infrared blocking mask 220 through the inkjet process is shown. The manufacturing process may proceed in order of the step (a), the step (b), and the step (c) in FIG. 4. First, referring to the step (a), a glass substrate 221 with foreign substances removed may be prepared, and a selective surface treatment SSM may be performed by specifying the area where infrared rays are transmitted. Through the selective surface treatment SSM, the accuracy of the inkjet process may be improved by preventing the material to be applied by the inkjet process from adhering to unnecessary areas. The hydrophobic material may be used for selective surface treatment SSM, but embodiments are not limited thereto. In the step (b), through the inkjet process, materials that reflect or absorb infrared rays may be applied excluding areas where infrared rays are transmit. For more detailed information about the material, the above description may be referred to. In the step (c), an infrared blocking layer 222 may be formed in the area where the material is applied through the inkjet process, and an infrared transmitting hole 223 may be formed in the area where the material is not applied through selective surface treatment.

As above-described, the method of manufacturing the infrared blocking mask 220 through the embodiment of FIG. 3 and FIG. 4 may not cause mask warping due to the large area process, unlike a manufacturing method of a general shadow mask and a fine metal mask (FMM). In case that there is no mask warping, the accuracy of the process through the mask may be improved.

Hereinafter, possible embodiments whose description was omitted in FIG. 1 are described through FIG. 5. FIG. 5 is a schematic cross-sectional view of a display panel according to an embodiment.

Referring to FIG. 5, an embodiment of the inkjet process of the organic light emitting-quantum dot light-emitting element convergence display panel is shown. For example, a display panel DP according to an embodiment may include a substrate SUB, a circuit element layer CL, and a light-emitting element layer EL.

The display panel DP according to an embodiment may include a substrate SUB. The substrate SUB may be a flexible substrate including a polymer such as polyimide, polyamide, or polyethylene terephthalate. The substrate SUB may be a rigid substrate including glass. The substrate SUB may include a flexible material such as plastic that is bent, bent, folded, or rolled, or includes a rigid substrate.

A circuit element layer CL may be disposed on the substrate SUB. The circuit element layer CL may include a buffer layer BF, a semiconductor layer ACT, a gate insulating layer GI, a gate electrode GE, an interlayer insulating layer IL1, and a passivation layer IL2.

The buffer layer BF of the circuit element layer CL may be disposed on the substrate SUB. In another example, the buffer layer BF may be omitted. The buffer layer BF may include a silicon nitride (SiNₓ), a silicon oxide (SiO₂), or a silicon oxynitride (SiOₓN_{y}). As the buffer layer BF is disposed between the substrate SUB and the semiconductor layer ACT, and blocks an impurity from the substrate SUB during a crystallization process to form a polycrystalline silicon, the characteristics of the polycrystalline silicon may be improved and the substrate SUB may be planarized, thereby alleviating the stress of the semiconductor layer AC formed on the buffer layer BF.

The semiconductor layer ACT may be disposed on the buffer layer BF. The semiconductor layer ACT may be made of a polycrystalline silicon or an oxide semiconductor. The semiconductor layer ACT may include a channel region C, a source region S, and a drain region D. The source region S and the drain region D may be positioned on both sides of the channel region C, respectively. The channel region C may be an intrinsic semiconductor whose impurity is not doped, and the source region S and the drain region D may be impurity semiconductors whose conductive impurity is doped. The semiconductor layer ACT may be made of an oxide semiconductor. For example, a separate protective layer may be added to protect the oxide semiconductor material, which is vulnerable to external environments such as high temperature.

A gate insulating layer GI may be disposed on the semiconductor layer ACT. The gate insulating layer GI may be a single layer or a multi-layer including at least one of a silicon nitride (SiNₓ), a silicon oxide (SiO₂), and a silicon oxynitride (SiOₓN_{y}).

The gate electrode GE may be disposed on the gate insulating layer GI. The gate electrode GE may be a multilayer including metal layers, which are stacked with each other and formed of at least one of copper (Cu), a copper alloy, aluminum (Al), an aluminum alloy, molybdenum (Mo), and a molybdenum alloy are stacked.

An interlayer insulating layer IL1 may be disposed above the gate electrode GE and the gate insulating layer GI. The interlayer insulating layer IL1 may include a silicon nitride (SiNₓ), a silicon oxide (SiO₂), or a silicon oxynitride (SiOₓN_{y}). An opening exposing the source region S and the drain region D, respectively, may be disposed in the interlayer insulating layer IL1.

A source electrode SE and a drain electrode DE may be disposed on the interlayer insulating layer IL1. The source electrode SE and the drain electrode DE may be respectively connected (e.g., electrically connected) to the source region S and the drain region D of the semiconductor layer ACT through the openings formed in the interlayer insulating layer IL1.

A passivation layer IL2 may be disposed above the interlayer insulating layer IL1, the source electrode SE, and the drain electrode DE. Since the passivation layer IL2 covers and planarizes the interlayer insulating layer IL1, the source electrode SE, and the drain electrode DE, and first electrodes E1a, E1b, and E1c may be formed on the passivation layer IL2 without steps or step differences. This passivation layer IL2 may be made of organic materials such as a polyacrylate resin, a polyimide resin, or a laminated film of organic materials and inorganic materials.

A light-emitting element layer EL may be disposed on the passivation layer IL2. The light-emitting element layer EL may include the first electrodes E1a, E1b, and E1c, a barrier rib PDL, pixel openings OP1, OP2, and OP3, first, second, and third light emitting layers EML1, EML2, and EML3, a second electrode E2, a capping layer CPL, and an encapsulation layer ENC.

The first electrodes E1a, E1b, and E1c of the light-emitting element layer EL may be disposed above the passivation layer IL2, which is the upper end portion of the circuit element layer CL. The first electrodes E1a, E1b, and E1c may be connected (e.g., electrically connected) to the drain electrode DE through the opening of the passivation layer IL2.

The driving transistor, which includes the gate electrode GE, the semiconductor layer ACT, the source electrode SE, and the drain electrode DE, may be connected (e.g., electrically connected) to the first electrodes E1a, E1b, and E1c and may supply a current to first, second, and third light-emitting elements ED1, ED2, and ED3. The display panel according to an embodiment, in addition to the driving transistor shown in FIG. 1, may further include a switching transistor connected (e.g., electrically connected) to a data line and transmitting a data voltage in response to a scan signal, and a compensation transistor connected (e.g., electrically connected) to the driving transistor and compensating a threshold voltage of the driving transistor in response to the scan signal.

The barrier rib PDL may be disposed on the passivation layer IL2 and the first electrodes E1a, E1b, and E1c. The barrier rib PDL may have pixel openings OP1, OP2, and OP3 that overlap the first electrodes E1a, E1b, and E1c) and define the light emitting area. The barrier rib PDL may include organic materials such as a polyacrylate resin, a polyimide resin, or silica-based inorganic materials. The pixel openings OP1, OP2, and OP3 may have a planar shape almost similar to the first electrodes E1a, E1b, and E1c, and may have a rhombus or octagonal shape similar to a rhombus in plan view, but embodiments are not limited thereto, and may have any shape such as a quadrangle, a polygon, etc.

According to an embodiment, the first light-emitting element ED1 may overlap a red light emission area RLA, the second light-emitting element ED2 may overlap a green light emission area GLA, and the third light-emitting element ED3 may overlap a blue light emission area BLA. The first light-emitting element ED1 may include the first electrode E1a, the first light emitting layer EML1, and the second electrode E2. The second light-emitting element ED2 may include the first electrode E1b, the second light emitting layer EML2, and the second electrode E2. The third light-emitting element ED3 may include the first electrode E1c, the third light emitting layer EML3, and the second electrode E2. The first, second, and third light-emitting elements ED1, ED2, and ED3 may further include a functional layer including at least one of a hole injection layer (HIL), a hole transport layer (HTL), an electron injection layer (EIL), and an electron transport layer (ETL). The function layer may include a part disposed between the first electrodes E1a, E1b, and E1c, and the first, second, and third light emitting layers EML1, EML2, and EML3, and a part disposed between the first, second, and third light emitting layers EML1, EML2, and EML3, and the second electrode E2.

The barrier rib PDL may function to separate or define the red light emission area RLA, the green light emission area GLA, and the blue light emission area BLA. The barrier rib PDL may have a first opening OP1 overlapping the red light emission area RLA, a green light emission area GLA overlapping the second opening OP2, and a blue light emission area BLA overlapping the third opening OP3.

A non-light emitting area NLA may be disposed between the red light emission area RLA, the green light emission area GLA, and the blue light emission area BLA. Each light emitting area may correspond to the light-emitting element. For example, the blue light emission area BLA, the red light emission area RLA, and the green light emission area GLA may correspond to a blue pixel, a red pixel, and a green pixel, respectively. Each shape and arrangement of the red light emission area RLA, the green light emission area GLA, and the blue light emission area BLA may be modified in various ways.

The first opening OP1 and the first electrode E1a of the first light-emitting element ED1 may overlap each other, the second opening OP2 and the first electrode E1b of the second light-emitting element ED2 may overlap each other, and the first opening OP3 and the first electrode E1c of the third light-emitting element ED3 may overlap each other. At least some of the first electrode E1a of the first light-emitting element ED1, the first electrode E1b of the second light-emitting element ED2, and the first electrode E1c of the third light-emitting element ED3 may overlap the barrier rib PDL. Using the barrier rib PDL as an example, the first electrode E1a of the first light-emitting element ED1, the first electrode E1b of the second light-emitting element ED2, and the first electrode E1c of the third light-emitting element ED3 may be spaced apart from each other.

The first light emitting layer EML1 may be disposed in the first opening OP1, the second light emitting layer EML2 may be disposed in the second opening OP2, and the third light emitting layer EML3 may be disposed in the third opening OP3. The first light emitting layer EML1, the second light emitting layer EML2, and the third light emitting layer EML3 may each be manufactured through the inkjet process.

The first light emitting layer EML1, the second light emitting layer EML2, and the third light emitting layer EML3 may emit light of different colors.

The first light emitting layer EML1 may emit red light. The first light emitting layer EML1 may include a first quantum dot QD1. The second light emitting layer EML2 may emit green light. The second light emitting layer EML2 may include a second quantum dot QD2.

The third light emitting layer EML3 may emit blue light. The third light emitting layer EML3 may include an organic material, such as a low molecular organic material or a polymer organic material with a molecular weight of 10,000 or more, such as poly(3,4-ethylenedioxythiophene) (PEDOT).

The quantum dots including the first quantum dot QD1 and the second quantum dot QD2 will now be described in detail below.

In the description, the quantum dots (hereinafter, referred to as semiconductor nanocrystals) may include a Group II-VI compound, a Group III-V compound, a Group IV-VI compound, a Group IV element or compound, a Group I-III-VI compound, a Group II-III-VI compound, a Group I-II-IV-VI compound, or a combination thereof.

The Group II-VI compound may be selected from the group consisting of a binary compound selected from the group consisting of CdSe, CdTe, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group II-VI compound may further include a Group III metal.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InNP, InNAs, InNSb, InPAs, InPSb, GaAlNP, and a mixture thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal (e.g., InZnP).

The Group IV-VI compound may be selected from the group consisting of a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof.

The Group IV element or compound may be a single substance of Si, Ge, or a combination thereof; or a binary element compound of SiC, SiGe, or a combination thereof, but embodiments are not limited thereto.

Examples of the Group I-III-VI compound may include CuInSe₂, CuInS₂, CuInGaSe, and CuInGaS, but embodiments are not limited thereto. Examples of the Group I-II-IV-VI compound may include CuZnSnSe and CuZnSnS, but embodiments are not limited thereto. The Group IV element or compound may be selected from a single substance selected from Si, Ge, and a mixture thereof, and a binary element compound selected from SiC, SiGe, and a mixture thereof.

The Group II-III-VI compound may be ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, or a combination thereof, but embodiments are not limited thereto.

The Group I-II-IV-VI compound may be selected from CuZnSnSe or CuZnSnS, but embodiments are not limited thereto.

In an embodiment, the quantum dots may not include cadmium. The quantum dots may include a semiconductor nanocrystal based on a Group III-V compound including indium and phosphorus. The Group III-V compound may further include zinc. The quantum dots may include a semiconductor nanocrystal based on a Group II-VI compound including a chalcogen element (e.g., sulfur, selenium, tellurium, or combinations thereof) and zinc.

In the quantum dots, the binary compound, the ternary compound, or the quaternary compound as above-described may be present in the particle at a uniform concentration or in the same particle of which a concentration distribution may be partially divided into different states. For example, they may have a core/shell structure in which one quantum dot surrounds another quantum dot. The interface between the core and the shell may have a concentration gradient in which the concentration of the elements present in the shell decreases toward the center.

In some embodiments, the quantum dots may have a core-shell structure including a core including the above-described nanocrystal and a shell surrounding the core. The shell of the quantum dot may function as a protective layer for maintaining the semiconductor characteristic by preventing a chemical modification of the core and/or a charging layer for imparting an electrophoretic characteristic to the quantum dot. The shell may be single-layered or multi-layered. The interface between the core and the shell may have a concentration gradient in which the concentration of elements present in the shell decreases toward the center. Examples of the shell of the quantum dot include a metal or non-metal oxide, a semiconductor compound, or a combination thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, however embodiments are not limited thereto.

For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, however embodiments are not limited thereto.

An interface between the core and the shell may have a concentration gradient, such that the concentration of an element existing in the shell is gradually reduced as it nears the center thereof. For example, the semiconductor nanocrystals may have a structure including one semiconductor nanocrystal core and multi-layered shells surrounding the core. In an embodiment, the multi-layered shells may have two or more layers, for example, two, three, four, five, or more layers. Two adjacent layers of the shell may have a single composition or different compositions. In the multi-layered shell, each layer may have a composition that varies along the radius.

The quantum dots may have a full width at half maximum (FWHM) of about 45 nm or less, about 40 nm or less, or about 30 nm or less, and may improve color purity or color reproducibility in this range. For example, since light emitted through the quantum dots is emitted in all directions, a wide viewing angle may be improved.

In the quantum dots, the shell material and the core material may have different energy bandgaps from each other. For example, the energy bandgap of the shell material may be greater than that of the core material. In another example, the energy bandgap of the shell material may be smaller than that of the core material. The quantum dots may have a multi-layered shell. In the multi-layered shell, the energy bandgap of the outer layer may be greater than the energy bandgap of the inner layer (e.g., the layer nearer to the core). In the multi-layered shell, the energy bandgap of the outer layer may be less than the energy bandgap of the inner layer.

The quantum dots may control an absorption wavelength or an emission wavelength by adjusting a composition and a size of the quantum dots. A maximum peak emission wavelength of the quantum dot may be an ultraviolet (UV) to infrared wavelength, or a wavelength of greater than the above wavelength range.

The quantum dot may have quantum efficiency of about 10% or more, for example, about 30% or more, about 50% or more, about 60% or more, about 70% or more, about 90% or more, or even 100%. The quantum dots may have a relatively narrow spectrum. The quantum dots may have a full width at half maximum of a light emission wavelength spectrum of, for example, about 50 nm or less, about 45 nm or less, about 40 nm or less, or about 30 nm or less.

The quantum dots may have a particle size of about 1 nm or more and about 100 nm or less. The size of the particle refers to the diameter of the particle or the diameter converted by assuming a sphere from a two-dimensional (2D) image obtained by an analysis with a transmission electron microscope. The quantum dots may have the size of about 1 nm to about 20 nm, for example, about 2 nm or more, about 3 nm or more, or about 4 nm or more, and about 50 nm or less, and about 40 nm or less, about 30 nm or less, about 20 nm or less, about 15 nm or less, or about 10 nm or less. The shape of the quantum dots is not limited thereto. For example, the shape of the quantum dots may include a sphere, a polyhedron, a pyramid, a multi-pod, a square, a cuboid, a nanotube, a nanorod, a nanowire, a nanosheet, or a combination thereof, but embodiments are not limited thereto.

The quantum dots may be commercially available or may be synthesized appropriately. For the quantum dots, the particle size may be controlled relatively freely during a colloid synthesis and the particle size may be uniformly controlled.

The quantum dots may include an organic ligand (e.g., having a hydrophobic moiety). The organic ligand moiety may be bound to surfaces of the quantum dots. The organic ligand moiety may include RCOOH, RNH₂, R₂NH, R₃N, RSH, R₃PO, R₃P, ROH, RCOOR, RPO(OH)₂, RHPOOH, R₂POOH, or combinations thereof, and herein, R is independently a C3 to C40 substituted or unsubstituted aliphatic hydrocarbon group such as a C3 to C40 (e.g., C5 or greater and C24 or smaller) substituted or unsubstituted alkyl, or a substituted or unsubstituted alkenyl, a C6 to C40 (e.g., C6 or greater and C20 or smaller) substituted or unsubstituted aromatic hydrocarbon group such as a substituted or unsubstituted C6 to C40 aryl group, or a combination thereof.

Examples of the organic ligand may be a thiol compound such as: methane thiol, ethane thiol, propane thiol, butane thiol, pentane thiol, hexane thiol, octane thiol, dodecane thiol, hexadecane thiol, octadecane thiol, or benzyl thiol; an amine such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; a phosphine compound such as methyl phosphine, ethyl phosphine, propyl phosphine, butyl phosphine, pentyl phosphine, octylphosphine, dioctyl phosphine, tributylphosphine, or trioctylphosphine; a phosphine compound or an oxide compound thereof such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, or trioctylphosphine oxide; a diphenyl phosphine, a triphenyl phosphine compound, or an oxide compound thereof; a C5 to C20 alkyl phosphonic acid such as hexylphosphinic acid, octylphosphinic acid, dodecanephosphinic acid, tetradecanephosphinic acid, hexadecanephosphinic acid, or octadecanephosphinic acid; and the like, but embodiments are not limited thereto. The quantum dots may include a hydrophobic organic ligand alone or in a mixture of at least two types of hydrophobic organic ligands. The hydrophobic organic ligand may not include a photopolymerizable moiety (e.g., an acrylate group, a methacrylate group, etc.).

Again, referring to FIG. 5, the second electrode E2 may be disposed on the function layer. The second electrode E2 may be disposed continuously over the red light emission area RLA, the green light emission area GLA, the blue light emission area BLA, and the non-light emitting area NLA. The second electrode E2 may receive a common voltage through a common voltage transmission part in the non-display area.

For example, the first electrodes E1a, E1b, and E1c may be an anode that is a hole injection electrode, and the second electrode E2 may be a cathode that is an electron injection electrode. However, embodiments are not limited thereto, and according to the driving method of the display panel, the first electrodes E1a, E1b, and E1c may become a cathode, and the second electrode E2 may become an anode.

The capping layer CPL may be disposed on the second electrode E2. The capping layer CPL may be disposed continuously over the red light emission area RLA, the green light emission area GLA, the blue light emission area BLA, and the non-light emitting area NLA.

An encapsulation layer ENC may be disposed on the capping layer CPL. The encapsulation layer ENC may seal the display layer by covering not only the upper surface but the side surfaces of the display layer including the first, second, and third light-emitting elements ED1, ED2, and ED3.

Since the light-emitting element is very vulnerable to moisture and oxygen, the encapsulation layer ENC may seal the display layer and may block the inflow of external moisture and oxygen. The encapsulation layer ENC may include a plurality of layers, and may be formed of a composite layer including both an inorganic layer and an organic layer. The encapsulation layer ENC may be formed of a triple layer in which an inorganic layer, an organic layer, and an inorganic layer are sequentially formed.

Again referring to FIG. 5, it shows a convergence type of display panel including the first and second light emitting layers EML1 and EML2, which are a quantum dot light emitting layer, and the third light emitting layer EML3, which is an organic emission layer. However, the bake temperatures of the quantum dot light emitting layer and the organic emission layer may be different. The efficiency according to the bake temperature of each light emitting layer is shown in Table 1 below.

TABLE 1

| Quantum dot light-emitting element | | Organic light emitting element | |
|---|---|---|---|
| Bake | Efficiency | Bake | Efficiency |
| temperature (° C.) | (Cd/A) | temperature (° C.) | (Cd/A) |
| 180 | 70.1 | 120 | 98.9 |
| 140 | 53.1 | 130 | 97.6 |
| 120 | 49.1 | 140 | 92.6 |
| | | 150 | 29 |

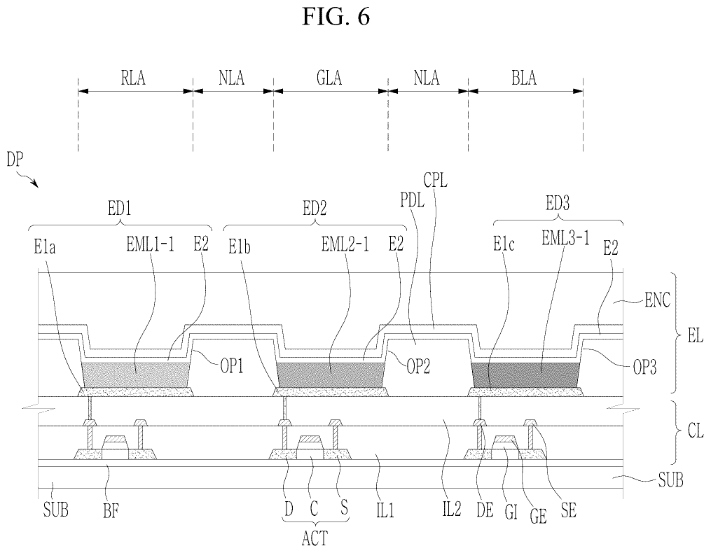

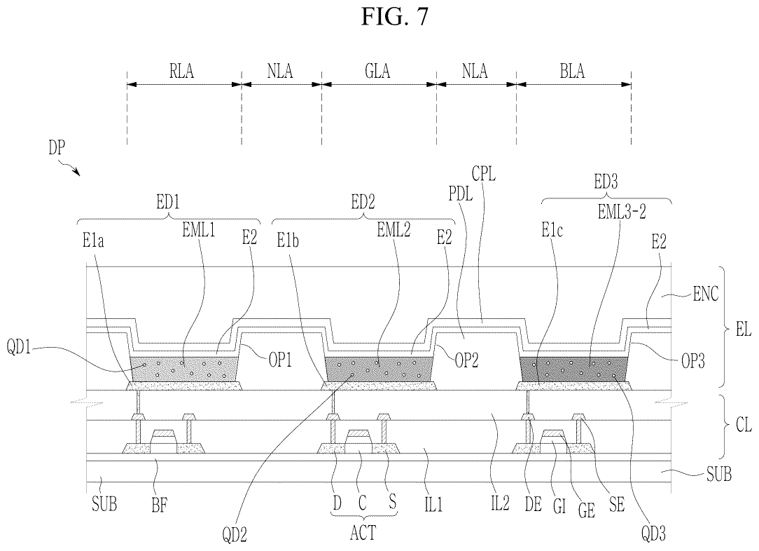

As shown in Table 1, the optimal bake temperature for the quantum dot light emitting layer is about 180° C., and in case that it is processed below about 140° C., a problem occurs in which the efficiency decreases sharply. The optimal bake temperature for the organic emission layer is about 140° C., and in case that it is processed above about 150° C., a problem occurs in which the efficiency decreases sharply. In case that the bake temperature of one of the quantum dot or the organic emission layer is used as a reference, the efficiency decreases significantly. To solve this problem, there is a method that divides the bake process into two stages in case of manufacturing the convergence type of display panel. In case of applying this two-stage manufacturing processes, a production time and a cost increase compared to non-convergence display panels. However, as shown in the disclosure, in case that the different temperatures may be applied to each light-emitting element, all light-emitting elements may be manufactured at once, significantly saving the production time and cost. Hereinafter, the display panel according to another embodiment is described with reference to FIG. 6 and FIG. 7. FIG. 6 is a schematic cross-sectional view of a display panel according to another embodiment. FIG. 7 is a schematic cross-sectional view of a display panel according to another embodiment. The description of the components that are the same as (or similar to) those described in FIG. 5 will be omitted.

Referring to FIG. 6, an embodiment of the inkjet process organic light emitting element display panel is shown. Unlike the embodiment of FIG. 5, first-first and second-first light emitting layers EML1-1 and EML2-1 may be formed instead of the first and second light emitting layers EML1 and EML2, and the first-first and second-first light emitting layers EML1-1 and EML2-1 may include an organic material instead of a quantum dot. Instead of the third light emitting layer EML3, the third-first light emitting layer EML3-1 may be formed, and a configuration material may be the same as the third light emitting layer EML3. For example, the third-first light emitting layer EML3-1, which emits blue light, may be difficult to secure the efficiency according to the high bake temperature compared with the first-first light emitting layer EML1-1, which emits red light and the second-first light emitting layer EML2-1, which emits green light. To solve this problem, it is necessary to apply the disclosure and perform the bake process for the third light-emitting element ED3 at the relatively lower temperature than the first and second light-emitting elements ED1 and ED2.

Referring to FIG. 7, an embodiment of the inkjet process quantum dot light-emitting element display panel is shown. Unlike the embodiment of FIG. 5, instead of the third light emitting layer EML3, a third-second light emitting layer EML3-2 may be formed, and the third-second light emitting layer EML3-2 may include a third quantum dot QD3 instead of an organic material. The more detailed information about the third quantum dot QD3 may refer to the above-mentioned first and second quantum dots QD1 and QD2.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A method for drying a display panel, the method comprising:
providing a display panel including a first light-emitting element, a second light-emitting element, and a third light-emitting element on a stage including a thermal heater;
providing an infrared heater on the stage;
providing an infrared blocking mask between the display panel and the infrared heater; and
baking at least one of the first light-emitting element and the second light-emitting element, and the third light-emitting element at different bake temperatures by the thermal heater and the infrared heater.

2. The method of claim 1, wherein
the infrared blocking mask includes an infrared transmitting hole at a position corresponding to the first light-emitting element and the second light-emitting element, and includes an infrared blocking layer at a position corresponding to the third light-emitting element.

3. The method of claim 2, wherein
the thermal heater applies heat to the first light-emitting element, the second light-emitting element, and the third light-emitting element, and
the infrared heater applies heat to the first light-emitting element and the second light-emitting element by the infrared transmitting hole.

4. The method of claim 2, wherein
the infrared blocking layer includes at least one of an infrared reflection layer or an infrared absorption layer.

5. The method of claim 1, wherein
the bake temperature for the third light-emitting element is lower than the bake temperature for the first light-emitting element and the second light-emitting element.

6. The method of claim 5, wherein
the first light-emitting element, the second light-emitting element, and the third light-emitting element each include one of an organic emission layer, a quantum dot light emitting layer, or an organic light emitting-quantum dot light emitting layer.

7. The method of claim 6, wherein
the first light-emitting element and the second light-emitting element include the quantum dot light emitting layer, and
the third light-emitting element includes the organic emission layer.

8. The method of claim 1, wherein
setting a temperature of heat provided by the thermal heater to be lower than a temperature of heat provided by the infrared heater.

9. The method of claim 1, wherein
providing the infrared blocking mask includes being mounted directly below the infrared heater or directly above the display panel.

10. The method of claim 1, wherein
the first light-emitting element, the second light-emitting element, and the third light-emitting element emit different colors of light.

11. A method for drying a display panel, the method comprising:
providing a display panel including a first light-emitting element, a second light-emitting element, and a third light-emitting element on a stage including a thermal heater;
providing an infrared blocking mask on the stage;
providing an infrared heater on the infrared blocking mask; and
baking at least one of the first light-emitting element, the second light-emitting element, and the third light-emitting element at different temperatures by the thermal heater and the infrared heater, wherein
the thermal heater applies heat to the first light-emitting element, the second light-emitting element, and the third light-emitting element,
the infrared heater applies heat to at least one of the first light-emitting element, the second light-emitting element, and the third light-emitting element due to the infrared blocking mask.

12. The method of claim 11, wherein
the infrared blocking mask includes an infrared blocking layer at a position corresponding to one or more of the first light-emitting element, the second light-emitting element, and the third light-emitting element.

13. The method of claim 12, wherein
the infrared blocking layer includes at least one of an infrared reflection layer or an infrared absorption layer.

14. The method of claim 11, wherein
setting a temperature of the heat provided by the thermal heater to be lower than a temperature of the heat provided by the infrared heater.

15. The method of claim 11, further comprising:
mounting the infrared blocking mask directly below the infrared heater or directly above the display panel.

16. The method of claim 11, wherein
the infrared blocking mask is formed using at least one method of a photolithography or an inkjet process.

17. An apparatus for drying a display panel, the apparatus comprising:
a drying chamber;
a stage disposed inside the drying chamber and including a thermal heater;
an infrared blocking mask disposed on the stage; and
an infrared heater disposed on the infrared blocking mask.

18. The apparatus of claim 17, wherein
the infrared blocking mask includes an infrared blocking layer and an infrared transmitting hole.

19. The apparatus of claim 18, wherein
the infrared blocking layer includes at least one of an infrared reflection layer or an infrared absorption layer.

20. The apparatus of claim 17, wherein
the infrared blocking mask is disposed directly below the infrared heater.
